(19) United States
(12) Patent Application Publication
(10) Pub. No.: US 2025/0132097 A1
(43) Pub. Date: Apr. 24, 2025

(54) MULTILAYER CERAMIC CAPACITOR, PACKAGE, AND CIRCUIT BOARD

(71) Applicant: TAIYO YUDEN CO., LTD., Tokyo (JP)

(72) Inventor: Ayumi SHIROTA, Tokyo (JP)

(73) Assignee: TAIYO YUDEN CO., LTD., Tokyo (JP)

(21) Appl. No.: 19/007,723

(22) Filed: Jan. 2, 2025

Related U.S. Application Data
(63) Continuation of application No. PCT/JP2023/025485, filed on Jul. 10, 2023.

(30) Foreign Application Priority Data
Jul. 15, 2022 (JP) 2022-114021

(51) Int. Cl. H01G 4/30; H01G 4/012; H05K 1/18

(52) U.S. Cl. CPC H01G 4/30; H01G 4/012; H05K 1/181; H05K 2201/10015

(57) ABSTRACT

A multilayer ceramic capacitor, which has a dimension in a first axis direction equal to or greater than 1.5 times a dimension in a second axis direction orthogonal to the first axis direction and is to be mounted on a mounting surface perpendicular to the first axis direction, includes a ceramic body having main surfaces perpendicular to the first axis, side surfaces perpendicular to the second axis, an end surface perpendicular to a third axis orthogonal to the first and second axes, a multilayer body having internal electrodes that are stacked in the second axis direction and led out to a connection end on the end surface, and margin portions covering the multilayer body from respective sides in the first axis direction, and having a higher concentration of a grain growth inhibiting element than the multilayer body, and an external electrode covering the end surface.

### CROSS-REFERENCE TO RELATED APPLICATION

This application is a continuation application of PCT/JP2023/025485 filed on Jul. 10, 2023, which claims priority to Japanese Patent Application No. 2022-114021 filed on Jul. 15, 2022, the entire contents of which are incorporated herein by reference.

### FIELD

A certain aspect of the present disclosure relates to a multilayer ceramic capacitor, a package, and a circuit board.

### BACKGROUND

As a method for manufacturing a multilayer ceramic capacitor, a technique is known in which a multilayer body having a structure in which internal electrodes are exposed on side surfaces is formed, and ceramic protective layers are subsequently attached to the side surfaces of the multilayer body, respectively as disclosed in Japanese Patent Application Laid-Open No. 2012-209539 (Patent Document 1). This technique is advantageous for increasing the capacitance of the multilayer ceramic capacitor because the ceramic protective layer can be made thin.

Further, Japanese Patent Application Laid-Open No. 2014-143392 (Patent Document 2) discloses a technique of inhibiting grain growth in the end portion of the dielectric layer between the internal electrodes adjacent to the ceramic protective layer by adding Mg, Mn, and a rare earth element to the ceramic protective layer. This technique can inhibit the occurrence of a short circuit between the internal electrodes due to grain growth in the end portion of the dielectric layer between the internal electrodes.

### SUMMARY

However, in the technique of adding Mg, Mn, a rare earth element, and the like to the ceramic protective layer, these additive elements diffuse into the dielectric layer, and thus the relative permittivity of the dielectric layer may be decreased or oxidation of the internal electrode may be promoted. These factors tend to cause a decrease in capacitance in multilayer ceramic capacitors.

It is generally known that increasing the number of stacked dielectric layers is effective as a method for increasing the capacitance of a multilayer ceramic capacitor. However, when the number of stacked dielectric layers is increased, the contact area between the dielectric layers and the ceramic protective layer is increased, and thus a decrease in capacitance due to the diffusion of the additive elements is more likely occur.

In view of the above circumstances, it is an object of the present disclosure to provide a multilayer ceramic capacitor, a package, and a circuit board that can inhibit the occurrence of a short circuit while securing a large capacitance in a tall multilayer ceramic capacitor.

A multilayer ceramic capacitor according to an embodiment of the present disclosure has a dimension in a first direction along a first axis equal to or greater than 1.5 times a dimension in a second direction along a second axis orthogonal to the first axis, and is to be mounted on a mounting surface perpendicular to the first axis.

The multilayer ceramic capacitor includes a ceramic body and an external electrode.

The ceramic body has a pair of main surfaces perpendicular to the first axis, a pair of side surfaces perpendicular to the second axis, an end surface perpendicular to a third axis orthogonal to the first axis and the second axis, a multilayer body having a plurality of external electrodes that are stacked in the second direction and are led out to a connection end on the end surface, and a pair of margin portions that cover the multilayer body from respective sides in the first direction, and have a higher concentration of a grain growth inhibiting element than the multilayer body.

The external electrode covers the end surface.

The grain growth inhibiting element is preferably at least one of the following elements: Mg, Mn, and a rare earth element.

A multilayer ceramic capacitor according to another embodiment of the present disclosure has a dimension in a first direction along a first axis equal to or greater than 1.3 times a dimension in a second direction along a second axis orthogonal to the first axis, and is to be mounted on a mounting surface perpendicular to the first axis.

The multilayer ceramic capacitor includes a ceramic body and an external electrode.

The ceramic body has a pair of main surfaces perpendicular to the first axis, a pair of side surfaces perpendicular to the second axis, an end surface perpendicular to a third axis orthogonal to the first axis and the second axis, a multilayer body having a plurality of internal electrodes that are stacked in the second direction and led out to a connection end on the end surface, and a pair of margin portions that cover the multilayer body from respective sides in the first direction and have a higher concentration of a grain growth inhibiting element than the multilayer body.

The external electrode covers the end surface.

The grain growth inhibiting element is preferably at least one of the following elements: Mg, Mn, and a rare earth element.

In this multilayer ceramic capacitor, in a tall structure having a larger dimension in the height direction, the stacking direction of the internal electrodes in the multilayer body is set to be the width direction having a smaller dimension. This allows the contact area between the margin portion and the multilayer body to be reduced, and furthermore, allows the pair of margin portions to be arranged at a large distance from each other in the height direction.

Therefore, in the multilayer ceramic capacitor, a wide section that is not affected by the diffusion of the grain growth inhibiting elements contained in the margin portion of the multilayer body can be secured. Thus, in the multilayer ceramic capacitor, a decrease in capacitance due to diffusion of the grain growth inhibiting elements in the multilayer body is less likely to occur, and thus a large capacitance is more likely to be ensured.

In addition, in the multilayer ceramic capacitor, since the total volume of the pair of margin portions covering the multilayer body can be made to be small, the absolute amount of the grain growth inhibiting element added to the pair of margin portions can be reduced. Thus, the multilayer ceramic capacitor can be manufactured at a reduced cost.

In the above ceramic body, the pair of main surfaces preferably have a higher flatness than the pair of side surfaces.

This allows the main surface of the ceramic body to be more securely sucked and placed on the mounting surface in a more stable posture when the multilayer ceramic capacitor is mounted.

The plurality of internal electrodes preferably have larger distances from the pair of main surfaces at the connection end than in a central portion in a third direction along the third axis.

In the plurality of internal electrodes, a dimension of the connection end in the first direction is preferably equal to or greater than 60% of and equal to or less than 90% of a dimension in the first direction of the central portion in the third direction.

These configurations achieve the structure in which the internal electrodes are absent in the vicinities of the ridge portions along the stacking direction of the ceramic body. Therefore, stress concentration due to expansion of the internal electrodes caused by diffusion of elements constituting the external electrode is less likely to occur.

In the above multilayer body, the concentration of the grain growth inhibiting element is preferably substantially constant in a section where the connection end is present in the first direction.

This allows the multilayer ceramic capacitor to more reliably ensure a large capacitance.

A package according to an embodiment of the present disclosure includes the above multilayer ceramic capacitor, a carrier tape, and a top tape.

The carrier tape has a sealing surface perpendicular to the first axis, and a recess that is recessed from the sealing surface in the first direction and accommodates the multilayer ceramic capacitor.

The top tape is attached to the sealing surface and covers the recess.

A circuit board according to an embodiment of the present disclosure includes the above multilayer ceramic capacitor and a mounting substrate.

The mounting substrate includes a mounting surface perpendicular to the first axis, and a connection electrode that is provided on the mounting surface and connected to the external electrode of the multilayer ceramic capacitor through solder.

### BRIEF DESCRIPTION OF THE DRAWINGS

FIG. 1 is a perspective view of a multilayer ceramic capacitor according to a first embodiment of the present disclosure;

FIG. 2 is a cross-sectional view of the multilayer ceramic capacitor taken along line A1-A1′ in FIG. 1;

FIG. 3 is a cross-sectional view of the multilayer ceramic capacitor taken along line B1-B1′ of FIG. 1;

FIG. 4 is a partially exploded view of an electrode stacking portion of the multilayer ceramic capacitor;

FIG. 5 is a graph presenting the concentration distribution of the grain growth inhibiting element in the ceramic body of the multilayer ceramic capacitor;

FIG. 6A and FIG. 6B illustrate a method of comparing the flatness of the main surface and the flatness of the side surface of the ceramic body of the multilayer ceramic capacitor;

FIG. 7 is a flowchart illustrating a method for manufacturing the multilayer ceramic capacitor;

FIG. 8A, FIG. 8B, and FIG. 8C are plan views of ceramic sheets prepared in step S01;

FIG. 9 schematically illustrates step S02;

FIG. 10 is a plan view illustrating step S03;

FIG. 11A, FIG. 11B, and FIG. 11C are cross-sectional views illustrating step S03;

FIG. 12A and FIG. 12B are cross-sectional views illustrating step S04;

FIG. 13 is a side view of a circuit board including the multilayer ceramic capacitor;

FIG. 14 is a partial plan view of a package of the multilayer ceramic capacitor;

FIG. 15 is a cross-sectional view of the package taken along line D-D′ in FIG. 13;

FIG. 16 is a cross-sectional view of the multilayer ceramic capacitor in accordance with a second embodiment taken along the line A2-A2′ in FIG. 1;

FIG. 17 is a cross-sectional view of the multilayer ceramic capacitor taken along line B2-B2′ in FIG. 1;

FIG. 18 is a partially exploded view of an electrode stacking portion of the multilayer ceramic capacitor; and

FIG. 19 is a graph presenting the concentration distribution of the grain growth inhibiting element in the ceramic body of the multilayer ceramic capacitor.

### DETAILED DESCRIPTION

Hereinafter, a multilayer ceramic capacitor 10 according to an embodiment of the present disclosure will be described with reference to the drawings. In the drawings, an X-axis, a Y-axis, and a Z-axis orthogonal to each other are appropriately illustrated. The X-axis, the Y-axis, and the Z-axis define a fixed coordinate system fixed with respect to the multilayer ceramic capacitor 10.

### First Embodiment

### [Structure of Multilayer Ceramic Capacitor 10]

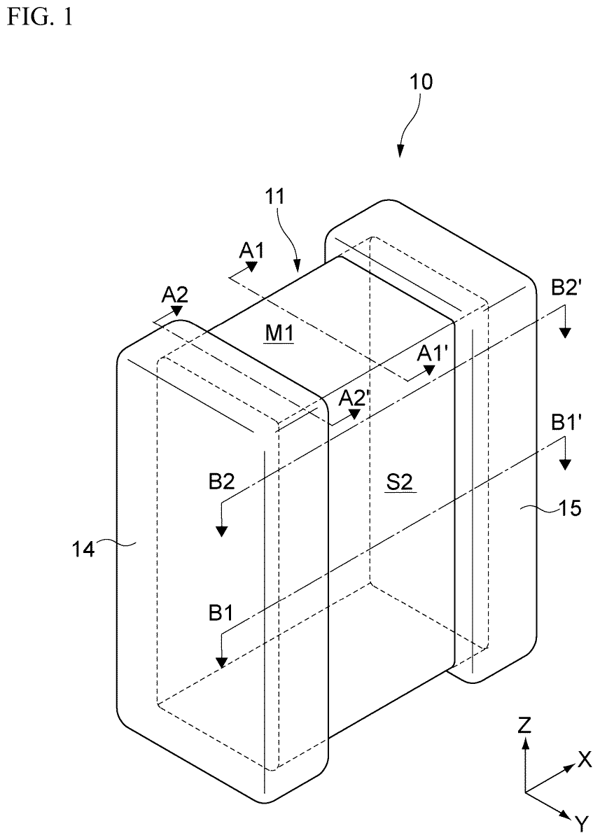

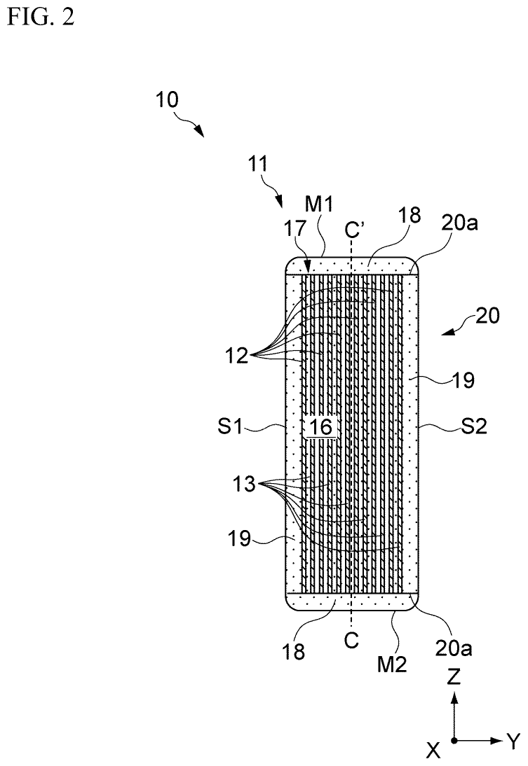

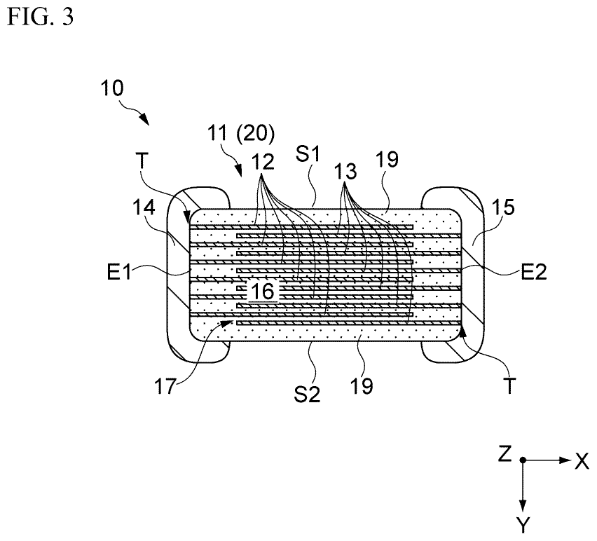

FIG. 1 to FIG. 3 illustrate the multilayer ceramic capacitor 10 according to a first embodiment of the present disclosure. FIG. 1 is a perspective view of the multilayer ceramic capacitor 10. FIG. 2 is a cross-sectional view of the multilayer ceramic capacitor 10 taken along line A1-A1′ in FIG. 1. FIG. 3 is a cross-sectional view of the multilayer ceramic capacitor 10 taken along line B1-B1′ in FIG. 1.

FIG. 2 and FIG. 3 illustrate a cross section of a section including the central portion of the multilayer ceramic capacitor 10. Specifically, FIG. 2 illustrates a vertical cross section along the Y-Z plane of the central portion in the X-axis direction of the multilayer ceramic capacitor 10. FIG. 3 illustrates a horizontal cross section along the X-Y plane of the central portion in the Z-axis direction in the multilayer ceramic capacitor 10.

The multilayer ceramic capacitor 10 includes a ceramic body 11, a first external electrode 14, and a second external electrode 15. The ceramic body 11 is configured as a hexahedron having first and second main surfaces M1 and M2 orthogonal to the Z-axis, first and second end surfaces E1 and E2 orthogonal to the X-axis, and first and second side surfaces S1 and S2 orthogonal to the Y-axis.

The main surfaces M1 and M2, the end surfaces E1 and E2, and the side surfaces S1 and S2 of the ceramic body 11 are all flat surfaces. A flat surface in the present embodiment does not have to be strictly flat as long as it is a surface that is recognized as flat when viewed as a whole, and includes, for example, a surface with minute surface irregularities or a surface with a gently curved shape that exists within a predetermined area.

The multilayer ceramic capacitor 10 is a tall type in which the dimension in the height direction along the Z-axis is equal to or greater than 1.5 times the dimension in the width direction along the Y-axis. In the multilayer ceramic capacitor 10, the capacitance is increased by increasing the dimension in the height direction. This allows the multilayer ceramic capacitor 10 to be mounted in a mounting space limited in the width direction.

The multilayer ceramic capacitor 10 may be a tall type having a dimension H in the Z-axis direction equal to or greater than 1.3 times the dimension W in the Y-axis direction.

In the multilayer ceramic capacitor 10, the dimension in the length direction along the X axis may be larger or smaller than the dimension in the height direction as long as it is larger than the dimension in the width direction. In the multilayer ceramic capacitor 10, the dimensions in the X-axis direction, the Y-axis direction, and the Z-axis direction can be freely determined within respective ranges satisfying the above conditions.

Specifically, in the multilayer ceramic capacitor 10, for example, the dimension in the length direction along the X-axis can be 0.2 mm or greater and 1.2 mm or less, the dimension in the width direction along the Y-axis can be 0.1 mm or greater and 0.7 mm or less, and the dimension in the height direction along the Z-axis can be 0.15 mm or greater and 1.0 mm or less.

The first external electrode 14 extends inward in the X-axis direction from the end surface E1 of the ceramic body 11 along the main surfaces M1 and M2 and the side surfaces S1 and S2, and the second external electrode 15 extends inward in the X-axis direction from the end surface E2 of the ceramic body 11 along the main surfaces M1 and M2 and the side surfaces S1 and S2. The first and second external electrodes 14 and 15 are separated from each other on the main surfaces M1 and M2 and the side surfaces S1 and S2. As a result, in both external electrodes 14 and 15, the cross sections along the X-Y and X-Z planes are U-shaped.

Each of the external electrodes 14 and 15 contains a metal material as a main component. Examples of the metal material constituting the main component of the external electrodes 14 and 15 include copper (Cu), nickel (Ni), tin (Sn), palladium (Pd), platinum (Pt), silver (Ag), gold (Au), and alloys thereof. In the present embodiment, the main component refers to a component having the highest content ratio.

The ceramic body 11 includes a multilayer body 20 and a pair of margin portions 18. The multilayer body 20 is formed of dielectric ceramic and has a structure in which a plurality of dielectric layers 17 each having a plate shape extending along the X-Z plane are stacked in the Y-axis direction. The pair of margin portions 18 cover the multilayer body 20 from respective sides in the Z-axis direction and form the main surfaces M1 and M2 of the ceramic body 11, respectively.

The multilayer body 20 includes an electrode stacking portion 16 and a pair of cover portions 19. The pair of cover portions 19 cover the electrode stacking portion 16 from respective sides in the Y-axis direction. Thus, the side surfaces S1 and S2 of the ceramic body 11 are defined by the pair of cover portions 19 and end portions of the pair of margin portions 18 in the Y-axis direction.

The electrode stacking portion 16 includes a plurality of first and second internal electrodes 12 and 13. In the electrode stacking portion 16, the internal electrodes 12 and 13 are disposed between the dielectric layers 17. The internal electrodes 12 and 13 are alternately arranged along the Y-axis direction, and face each other in the Y-axis direction in the opposing section located in the center in the X-axis and Z-axis directions.

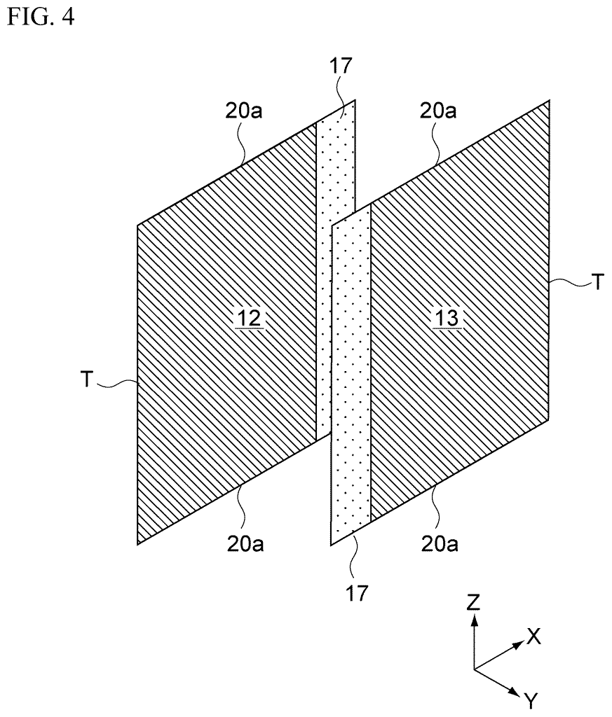

FIG. 4 is a partially exploded view of the electrode stacking portion 16. Specifically, FIG. 4 illustrates one dielectric layer 17 on which the first internal electrode 12 is formed and one dielectric layer 17 on which the second internal electrode 13 is formed, among the dielectric layers 17 constituting the electrode stacking portion 16. Each of the internal electrodes 12 and 13 has a rectangular planar shape.

The internal electrodes 12 and 13 contain a metal material as a main component. The metal material constituting the main component of the internal electrodes 12 and 13 is typically nickel (Ni), but also copper (Cu), palladium (Pd), platinum (Pt), silver (Ag), gold (Au), alloys thereof, or the like.

The first internal electrodes 12 are led out from the opposing section to the connection end T on the first end surface E1 and are connected to the first external electrode 14 at the connection end T. The second internal electrodes 13 are led out from the opposing section to the connection end T on the second end surface E2 and are connected to the second external electrode 15 at the connection end T on the second end surface E2.

With such a configuration, in the multilayer ceramic capacitor 10, when a voltage is applied between the external electrodes 14 and 15, the voltage is applied to the dielectric layers 17 between the internal electrodes 12 and 13 in the opposing section. As a result, in the multilayer ceramic capacitor 10, electric charge corresponding to the voltage between the external electrodes 14 and 15 is stored.

In the ceramic body 11, a dielectric ceramic having a high dielectric constant is used in order to increase the capacitance of each dielectric layer 17 between the internal electrodes 12 and 13. Examples of the dielectric ceramic having a high dielectric constant include a material having a perovskite structure represented by a general formula ABO₃, which contains barium (Ba) and titanium (Ti), and is represented by barium titanate (BaTiO₃).

The dielectric ceramic may be a composition system such as strontium titanate (SrTiO₃), calcium titanate (CaTiO₃), magnesium titanate (MgTiO₃), calcium zirconate (CaZrO₃), calcium zirconate titanate (Ca(Zr,Ti)O₃), barium calcium zirconate titanate ((Ba, Ca)(Zr,Ti)O₃), barium zirconate (BaZrO₃), or titanium dioxide (TiO₂).

The external electrodes 14 and 15 are typically configured as fired films formed by firing a conductor paste on each of the end surfaces E1 and E2 of the ceramic body 11.

However, the external electrodes 14 and 15 are not limited to the fired films, and may be configured as, for example, sputtered films formed by sputtering.

In the multilayer ceramic capacitor 10, a conductor layer covering each of the external electrodes 14 and 15 may be provided to improve solder wettability and moisture resistance. Examples of such a conductor layer include a conductor plating layer formed by wet plating. The conductor plating layer may have a single-layer structure or a multilayer structure.

In the process of manufacturing the multilayer ceramic capacitor 10, the pair of margin portions 18 are attached to respective covering surfaces 20a of the multilayer body 20 perpendicular to the Z-axis in an unfired stage, thereby forming the ceramic body 11. Therefore, in the multilayer ceramic capacitor 10, the pair of margin portions 18 can be formed of a component different from that of the dielectric layers 17 of the multilayer body 20.

In the multilayer ceramic capacitor 10, a grain growth inhibiting element having an effect of inhibiting grain growth of crystal grains of polycrystals constituting the dielectric ceramic is added more to the pair of margin portions 18 than to the dielectric layers 17 of the multilayer body 20. The grain growth inhibiting elements contained in the pair of margin portions 18 diffuse into the dielectric layers 17 of the multilayer body 20 during firing.

The grain growth inhibiting element can be freely selected from elements having an effect of inhibiting grain growth of the dielectric ceramic. Specifically, as the grain growth inhibiting element, for example, at least one of the following elements: magnesium (Mg), manganese (Mn), and rare earth elements (yttrium (Y), dysprosium (Dy), holmium (Ho), erbium (Er), ytterbium (Yb), and the like) can be used.

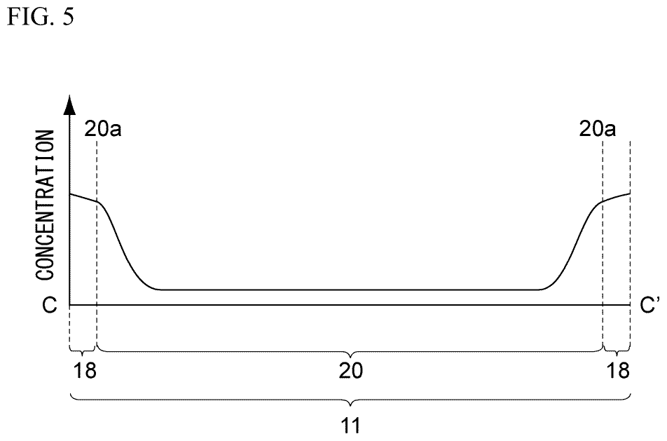

FIG. 5 is a graph presenting the concentration distribution of the grain growth inhibiting element along the line C-C′ in FIG. 2 in the ceramic body 11 after firing. That is, FIG. 5 presents the concentration distribution of the grain growth inhibiting element along the Z-axis direction in the central portion of the ceramic body 11 in the X-axis and Y-axis directions. In FIG. 5, the horizontal axis represents the position, and the vertical axis represents the concentration of the grain growth inhibiting element.

As presented in FIG. 5, the concentration of the grain growth inhibiting element in the ceramic body 11 is higher in the pair of margin portions 18 than in the multilayer body 20. In the multilayer body 20, the concentration of the grain growth inhibiting element increases at closer distances to the covering surfaces 20a in the vicinities of the covering surfaces 20a due to the diffusion of the grain growth inhibiting elements from the pair of margin portions 18.

Near the covering surfaces 20a of the multilayer body 20, since the dielectric layers 17 are close to the main surfaces M1 and M2, heat is easily applied during firing, and the grain growth of the dielectric layers 17 easily progresses. As the grain growth of the dielectric layers 17 progresses, the internal electrodes 12 and 13 are spheroidized and become thicker in the stacking direction, and the distance between the adjacent internal electrodes 12 and 13 is narrowed, so that a short circuit is likely to occur.

In this regard, near the covering surfaces 20a in the multilayer body 20 according to the present embodiment, as presented in FIG. 5, the concentration of the grain growth inhibiting element is higher in the sections closer to the main surfaces M1 and M2, and the effect of inhibiting the grain growth of the dielectric layers 17 during firing is effectively obtained. Therefore, in the multilayer ceramic capacitor 10, a short circuit between the internal electrodes 12 and 13 is unlikely to occur.

In the multilayer body 20, the dimension in the Z-axis direction is large, and the pair of margin portions 18 covering the respective covering surfaces 20a are disposed to be largely separated from each other in the Z-axis direction. Therefore, in the multilayer body 20, the section where the concentration of the grain growth inhibiting element is low in the central portion in the Z-axis direction without being affected by the diffusion of the grain growth inhibiting elements from the pair of margin portions 18 can be increased.

Thus, in the multilayer ceramic capacitor 10, a decrease in capacitance due to the influence of diffusion of the grain growth inhibiting elements can be inhibited. From this viewpoint, the dimension in the Z-axis direction of the section of the multilayer body 20 that is not affected by the diffusion of the grain growth inhibiting elements from the pair of margin portions 18 is preferably set to be equal to or greater than 70% of the dimension in the Z-axis direction of the entire multilayer body 20.

Here, in the multilayer body 20, the section that is not affected by the diffusion of the grain growth inhibiting elements from the pair of margin portions 18 can be defined as a section where the concentration of the grain growth inhibiting element in the central portion in the Z-axis direction is substantially constant. The section where the concentration of the grain growth inhibiting element is substantially constant means a section where the concentration of the grain growth inhibiting element with respect to the B-site element of the dielectric ceramic constituting the dielectric layer 17 is zero, or a section where the concentration of the grain growth inhibiting element with respect to the B-site element at the center in the Z-axis direction is within +0.1%.

As described above, in the multilayer ceramic capacitor 10, the grain growth inhibiting elements are diffused from the pair of margin portions 18 into the multilayer body 20, and thus, it is possible to reliably inhibit grain growth in the sections on both sides in the Z-axis direction where grain growth easily progresses during firing while minimizing a decrease in capacitance due to the diffusion of the grain growth inhibiting elements.

In the multilayer body 20, the stacking direction of the dielectric layers 17 is the Y-axis direction having a smaller dimension, and thus the contact areas of the covering surfaces 20a with the pair of margin portions 18 are small. Therefore, in the multilayer body 20, the amount of diffusion of the grain growth inhibiting elements contained in the pair of margin portions 18 through the covering surfaces 20a can be kept small, making it easier to ensure a large capacitance.

Furthermore, in the ceramic body 11, the areas of the covering surfaces 20a of the multilayer body 20 covered with the pair of margin portions 18 are small, and thus the total volume of the pair of margin portions 18 can be kept small. This can reduce the absolute amount of the grain growth inhibiting element added to the pair of margin portions 18, and thus can reduce the manufacturing cost.

In the multilayer ceramic capacitor 10 according to the present embodiment, as described above, the stacking direction of the dielectric layers 17 in the multilayer body 20 is the Y-axis direction having a smaller dimension, and thus the number of stacked internal electrodes 12 and 13 is smaller than that in the configuration in which the stacking direction of the dielectric layers 17 is the Z-axis direction having a larger dimension.

However, in the ceramic body 11 according to the present embodiment, the internal electrodes 12 and 13 are widened in the Z-axis direction in which the dimension is larger, and thus the area of the section where the internal electrodes 12 and 13 face each other can be increased. Therefore, in the multilayer ceramic capacitor 10, a large capacitance can be secured even when the number of stacked layers of the internal electrodes 12 and 13 in the ceramic body 11 is small.

Furthermore, in the multilayer ceramic capacitor 10, the dimensions of the internal electrodes 12 and 13 are increased in the Z-axis direction, and thus large connection areas with the external electrodes 14 and 15 at the connection ends T of the internal electrodes 12 and 13 can be secured. Thus, in the multilayer ceramic capacitor 10, the occurrence of poor connection between each of the internal electrodes 12 and 13 and the corresponding one of the external electrodes 14 and 15 is inhibited.

In the multilayer ceramic capacitor 10, the main surfaces M1 and M2 of the ceramic body 11 defined by the pair of margin portions 18 preferably have high flatness. In the present embodiment, the pair of margin portions 18 are attached to the multilayer body 20 in an unfired stage, and thus the ceramic body 11 having high flatness of the main surfaces M1 and M2 is easily obtained.

Accordingly, in the multilayer ceramic capacitor 10, the first main surface M1 having a high flatness in the ceramic body 11 can be more reliably sucked by the suction nozzle during mounting. In the multilayer ceramic capacitor 10, the stable posture in which the second main surface M2 with high flatness in the ceramic body 11 faces the mounting surface in parallel is less likely to be lost during mounting.

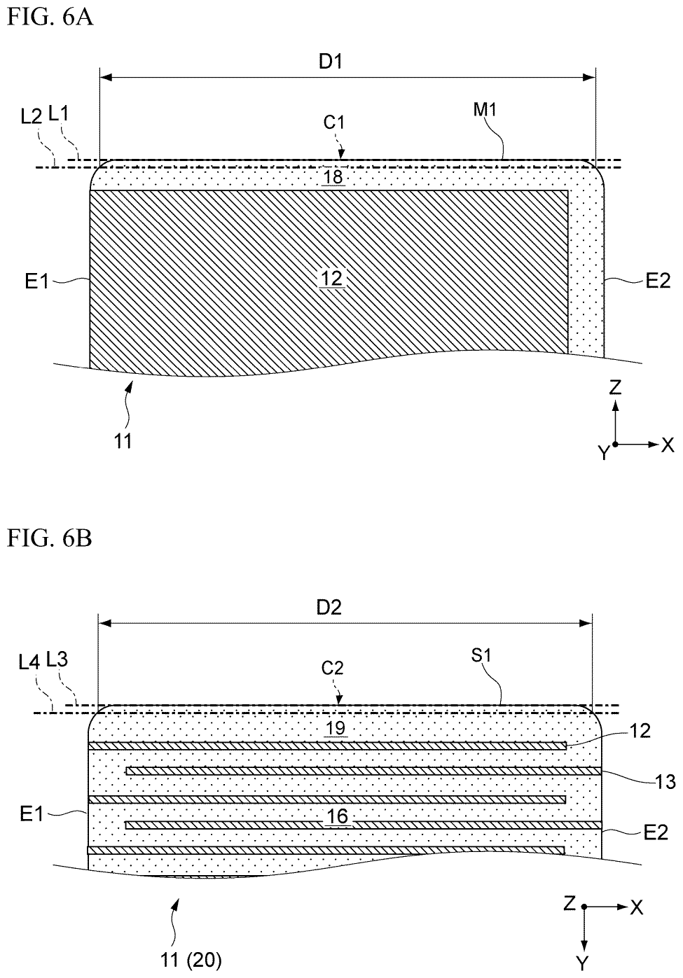

Specifically, in the ceramic body 11, the flatness of the main surfaces M1 and M2 is preferably higher than the flatness of the side surfaces S1 and S2. An example of a method of comparing the flatness of the main surfaces M1 and M2 and the flatness of the side surfaces S1 and S2 will be described below. FIG. 6A illustrates an example in which the first main surface M1 is the measurement target surface. FIG. 6B illustrates an example in which the first side surface S1 is the measurement target surface.

First, as illustrated in FIG. 6A, a cross section perpendicular to the first main surface M1 and parallel to the X-Z plane that bisects the first main surface M1 is exposed. In this cross section, a first imaginary line L1, which passes through the center point C1 in the X-axis direction of the first main surface M1 and is parallel to the X-axis, and a second imaginary line L2, which is parallel to the first imaginary line L1 and is separated from the first imaginary line L1 by an interval of 1% of the dimension of the ceramic body 11 in the Z-axis direction are defined. Then, the distance between two points where the second imaginary line L2 and the first main surface M1 intersect are measured as the dimension D1 of the flat region of the first main surface M1. The dimension D1 on the second main surface M2 is also measured in the same manner.

As illustrated in FIG. 6B, a cross section perpendicular to the first side surface S1 and parallel to the X-Y plane that bisects the first side surface S1 is exposed. In this cross section, a third imaginary line L3, which passes through the center point C2 in the X-axis direction of the first side surface S1 and is parallel to the X-axis, and a fourth imaginary line L4, which is parallel to the third imaginary line L3 and is separated from the third imaginary line L3 by an interval of 1% of the dimension of the ceramic body 11 in the Z-axis direction are defined. Then, the distance between two points where the fourth imaginary line L4 and the first side surface S1 intersect is measured as the dimension D2 of the flat region of the first side surface S1. The dimension D2 of the second side surface S2 is also measured in the same manner.

Then, for five or more multilayer ceramic capacitors 10, the mean value of the dimensions D1 on the main surfaces M1 and M2 and the mean value of the dimensions D2 on the side surfaces S1 and S2 are calculated. The calculated mean value of the dimension D1 and the calculated mean value of the dimension D2 are compared, and when the mean value of the dimension D1 is larger than the mean value of the dimension D2, it can be determined that the main surfaces M1 and M2 have higher flatness than the side surfaces S1 and S2.

### [Method of Manufacturing Multilayer Ceramic Capacitor 10]

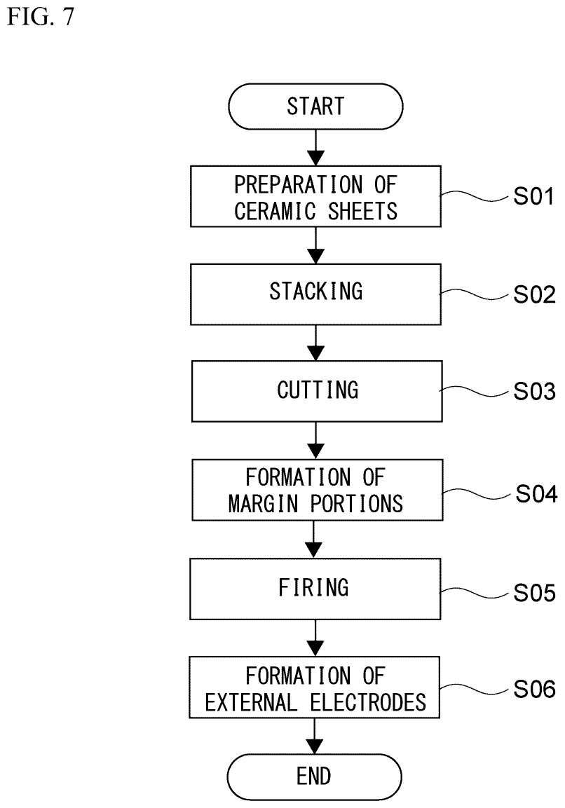

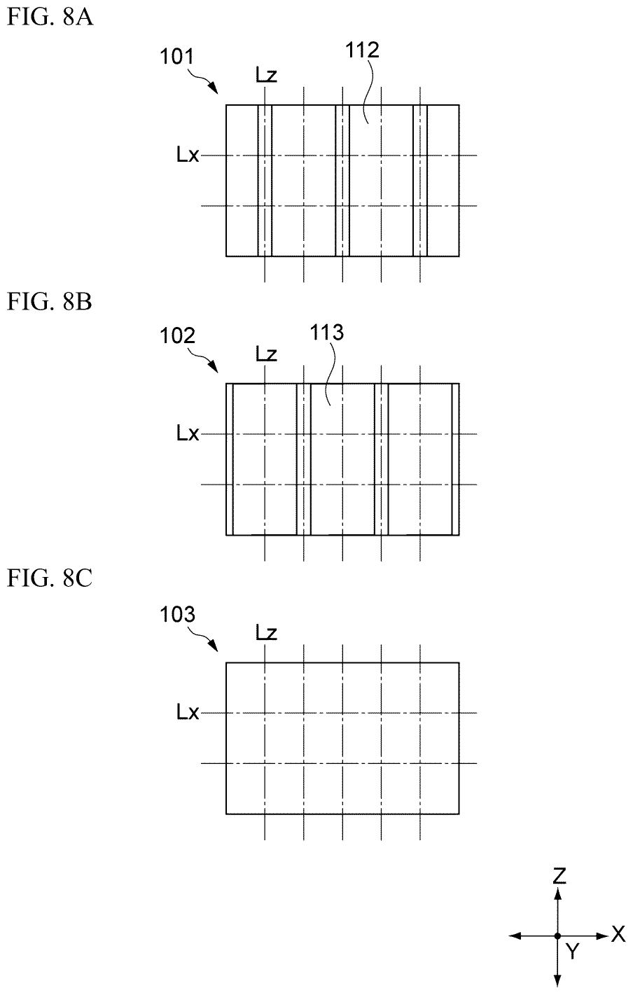

FIG. 7 is a flowchart illustrating a method of manufacturing the multilayer ceramic capacitor 10 according to the present embodiment. FIG. 8A to FIG. 12B illustrate a process of manufacturing the multilayer ceramic capacitor 10. Hereinafter, a method of manufacturing the multilayer ceramic capacitor 10 will be described along with FIG. 7, referring to FIG. 8A to FIG. 12B as appropriate.

### (Step S01: Preparation of Ceramic Sheets)

In step S01, first and second ceramic sheets 101 and 102 for forming the electrode stacking portion 16 and third ceramic sheets 103 for forming the pair of cover portions 19 are prepared as ceramic sheets constituting the multilayer body 20. FIG. 8A, FIG. 8B, and FIG. 8C are plan views of the ceramic sheets 101, 102, and 103, respectively.

The ceramic sheets 101, 102, and 103 prepared in step S01 are each formed as an unfired dielectric green sheet containing a dielectric ceramic as a main component. The ceramic sheets 101,102, and 103 are each formed into a sheet shape by using, for example, a roll coater or a doctor blade.

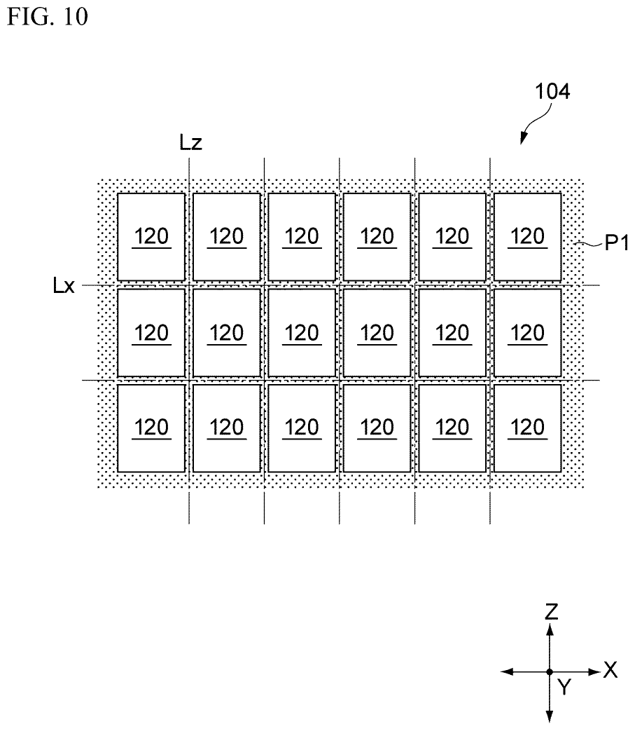

At this stage, each ceramic sheet 101,102, 103 is configured as a large-sized sheet that has not been separated into individual pieces. In FIG. 8A, FIG. 8B, FIG. 8C, and FIG. 10, first cut lines Lx parallel to the X-axis and second cut lines Lz parallel to the Z-axis are indicated by dash-dotted lines as cut lines for separating the multilayer ceramic capacitors 10 into individual pieces.

Unfired conductor patterns 112 and 113 corresponding to the internal electrodes 12 and 13 are formed on the ceramic sheets 101 and 102 constituting the electrode stacking portion 16, respectively. On the other hand, no unfired conductor pattern is formed on the third ceramic sheets 103 corresponding to the pair of cover portions 19 in which no internal electrodes are provided.

The conductor patterns 112 and 113 are formed by applying a conductive paste containing a metal material as a main component to the ceramic sheets 101 and 102, respectively. The method for applying the conductive paste can be freely selected from known techniques, and for example, a screen printing method or a gravure printing method can be used.

In the conductor pattern 112, spaces extending along the cut lines Lz and having a width in the X-axis direction are formed with one cut line Lz interposed therebetween, and in the conductor pattern 112, spaces extending along the cut lines Lz and having a width in the X-axis direction are formed with one cut line Lz interposed therebetween. The spaces extending along the cut lines Lz of the conductor pattern 112 and the spaces extending along the cut lines Lz of the conductor pattern 113 are alternately arranged in the X-axis direction.

### (Step S02: Stacking)

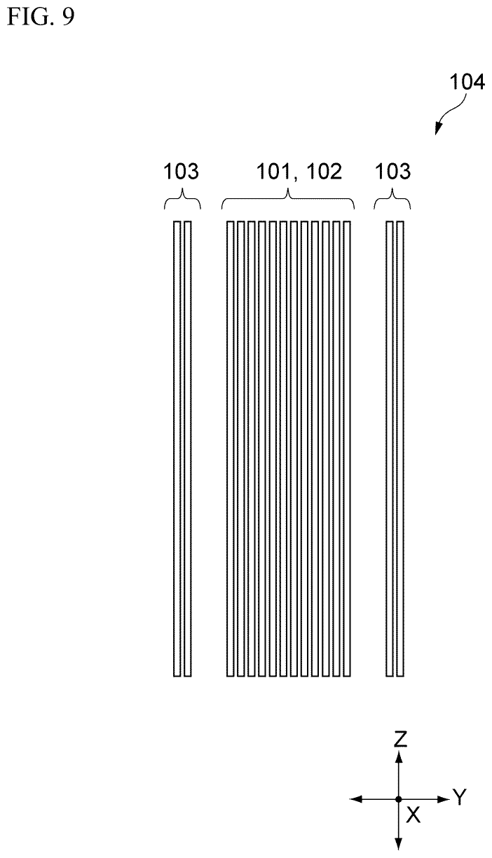

In step S02, the ceramic sheets 101, 102, and 103 prepared in step S01 are stacked as illustrated in FIG. 9 to produce a multilayer sheet 104. The multilayer sheet 104 is obtained by integrating the stacked ceramic sheets 101, 102, and 103 by hydrostatic pressurization, uniaxial pressurization, or the like.

In the multilayer sheet 104, the ceramic sheets 101 and 102 are alternately stacked in the Y-axis direction in the positions corresponding to the electrode stacking portion 16. In the multilayer sheet 104, the third ceramic sheets 103 corresponding to the pair of cover portions 19 are stacked on respective sides of the stacked ceramic sheets 101 and 102 in the Y-axis direction.

### (Step S03: Cutting)

In step S03, the multilayer sheet 104 obtained in step S02 is cut along the cut lines Lx and Lz as illustrated in FIG. 10, thereby obtaining unfired multilayer bodies 120. For example, a cutting device provided with a push-cutting blade or a dicing device provided with a rotary blade can be used to cut the multilayer sheet 104 in step S03.

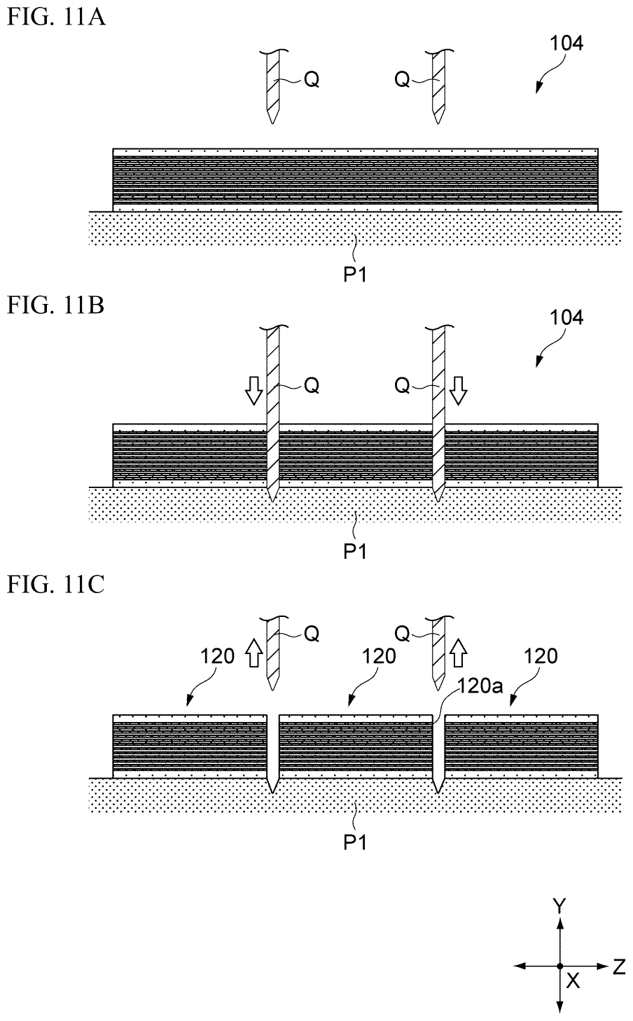

FIG. 11A, FIG. 11B, and FIG. 11C are schematic cross-sectional views illustrating an example of step S03. In the method illustrated in FIG. 11A to FIG. 11C, a cutting blade Q that is a push-cutting blade is used. First, as illustrated in FIG. 11A, the cutting blades Q directed downward in the Y-axis direction are disposed above the multilayer sheet 104 in the Y-axis direction. The lower surface of the multilayer sheet 104 in the Y-axis direction is attached to a tape P1.

Then, as illustrated in FIG. 11B, the multilayer sheet 104 is cut by moving the cutting blades Q downward in the Y-axis direction until the cutting blades Q reach the tape P1. Then, as illustrated in FIG. 11C, the cutting blades Q are moved upward in the Y-axis direction and pulled out from the multilayer sheet 104. Thus, the multilayer sheet 104 is separated into a plurality of multilayer bodies 120.

In the unfired multilayer body 120 obtained in step S03, cut surfaces 120a corresponding to the covering surfaces 20a of the fired multilayer body 20 are formed. In the multilayer body 120, the unfired conductor patterns 112 and 113 corresponding to the internal electrodes 12 and 13 in the fired multilayer body 20 are exposed on the respective cut surfaces 120a.

### (Step S04: Formation of Margin Portions)

In step S04, a pair of unfired margin portions 118 are formed on the respective cut surfaces 120a of the multilayer body 120 obtained in step S03. This process produces the unfired ceramic body 11. The pair of margin portions 118 are each formed by, for example, attaching ceramic sheets or applying a ceramic slurry.

Grain growth inhibiting elements are added to the material constituting the unfired margin portions 118 at a higher concentration than the material constituting the ceramic sheets 101,102, and 103. As a result, the ceramic body 11 after firing has a concentration distribution of the grain growth inhibiting element as presented in FIG. 5.

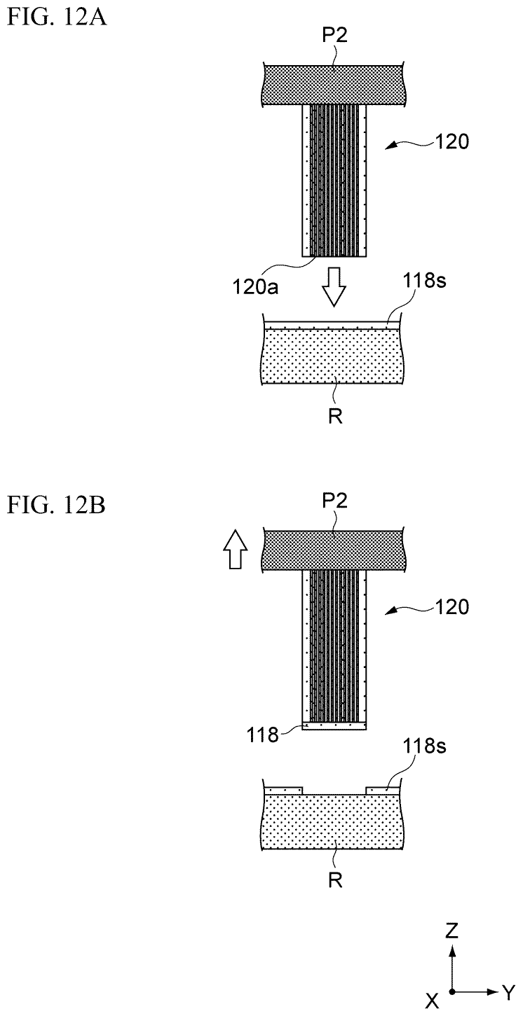

FIG. 12A and FIG. 12B are schematic cross-sectional views illustrating an example of step S04. In the method illustrated in FIG. 12A and FIG. 12B, a ceramic sheet 118s is used. The ceramic sheet 118s can be formed in the same manner as the ceramic sheets 101, 102, and 103. As illustrated in FIG. 12A, the ceramic sheet 118s is disposed on a flat elastic body R.

First, as illustrated in FIG. 12A, the cut surface 120a of the multilayer body 120 with the other cut surface 120a held by a tape P2, is opposed to the ceramic sheet 118s. Then, the multilayer body 120 is moved downward in the Z-axis direction together with the tape P2, and the cut surface 120a of the multilayer body 120 is pressed against the ceramic sheet 118s.

At this time, the ceramic sheet 118s is punched along the outline form of the cut surface 120a of the multilayer body 120 by the shearing force that is applied to the ceramic sheet 118s from the multilayer body 120. The portion of the ceramic sheet 118s punched out by the multilayer body 120 is attached to the cut surface 120a to form the unfired margin portion 118.

As illustrated in FIG. 12B, when the multilayer body 120 is moved upward in the Z-axis direction together with the tape P2, the multilayer body 120 with the margin portion 118 formed on the cut surface 120a is obtained. In the same manner, the margin portion 118 is formed on the cut surface 120a of the multilayer body 120 that was held by the tape P2, and thereby, the unfired ceramic body 11 is obtained.

As described above, the pair of margin portions 118 can be formed by attaching the ceramic sheets 118s having uniform thicknesses to the respective flat cut surfaces 120a of the multilayer body 120. This makes it easy to obtain high flatness on the main surfaces M1 and M2 constituted by the pair of margin portions 18 in the fired ceramic body 11.

### (Step S05: Firing)

In step S05, the ceramic body 11 obtained in step S04 is fired. The firing temperature in step S05 can be set to about 1000 to 1300° C., for example, when a barium titanate (BaTiO₃)-based material is used. The firing can be performed, for example, in a reducing atmosphere or a low oxygen partial pressure atmosphere.

In step S05, the grain growth inhibiting elements contained in the margin portions 118 diffuse into the multilayer body 120 through the cut surfaces 120a in the process of firing the dielectric ceramic. As a result, the multilayer body 120 becomes the multilayer body 20, the margin portion 118 becomes the margin portion 18, and the ceramic body 11 having the concentration distribution of the grain growth inhibiting element presented in FIG. 5 is obtained.

### (Step S06: Formation of External Electrodes)

In step S06, the multilayer ceramic capacitor 10 illustrated in FIG. 1 to FIG. 3 is produced by forming the external electrodes 14 and 15 on respective end portions in the X-axis direction of the ceramic body 11 obtained in step S05. The external electrodes 14 and 15 are formed by applying a conductive paste containing a metal material as a main component to the ceramic body 11 and firing the conductive paste.

### [Mounting of Multilayer Ceramic Capacitor 10]

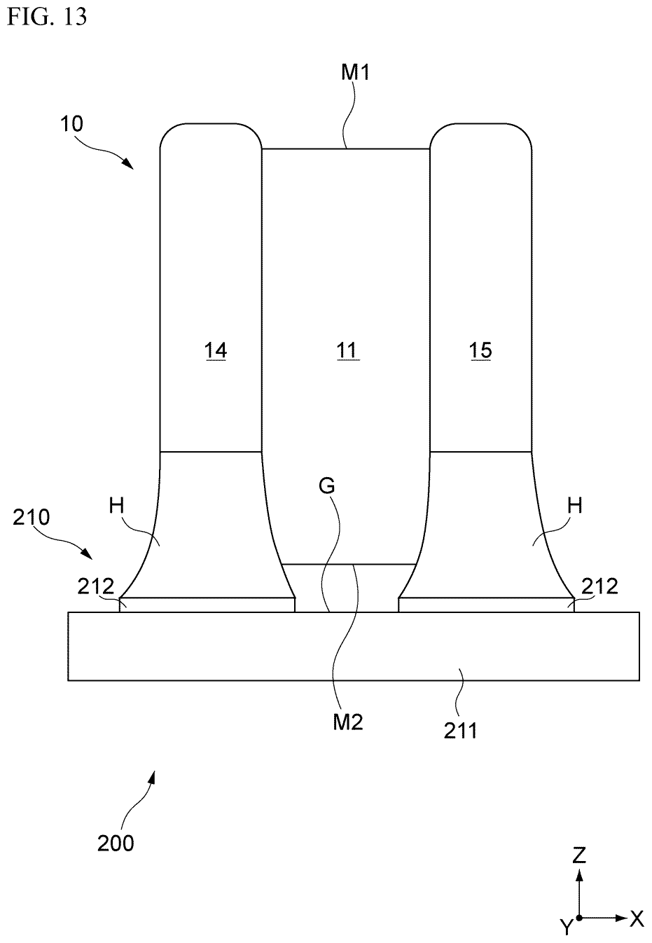

FIG. 13 is a side view of a circuit board 200 including the multilayer ceramic capacitor 10 according to the present embodiment. The circuit board 200 includes a mounting substrate 210 on which the multilayer ceramic capacitor 10 is mounted. The mounting substrate 210 includes a base material 211 that extends along the X-Y plane and has a mounting surface G perpendicular to the Z-axis, and a pair of connection electrodes 212 provided on the mounting surface G.

In the circuit board 200, the external electrodes 14 and 15 of the multilayer ceramic capacitor 10 are connected to the pair of connection electrodes 212 of the mounting substrate 210, respectively, with solder H interposed therebetween. As a result, in the circuit board 200, the multilayer ceramic capacitor 10 is fixed to and electrically connected to the mounting substrate 210.

Here, in the multilayer ceramic capacitor 10, it is known that when a voltage is applied to the external electrodes 14 and 15 via the connection electrodes 212 of the mounting substrate 210 at the time of driving the circuit board 200, electrostriction occurs in the ceramic body 11 due to the piezoelectric effect. The electrostriction generated in the ceramic body 11 causes a relatively large deformation in the stacking direction of the internal electrodes 12 and 13.

In the circuit board 200, electrostriction occurs repeatedly in the multilayer ceramic capacitor 10 to which an AC voltage is applied, and thus vibration in the thickness direction may be generated in the base material 211 of the mounting substrate 210. In the circuit board 200, when the vibration generated in the base material 211 increases, a phenomenon called “sound emission” in which noise sound is generated from the base material 211 may occur.

In this regard, in the multilayer ceramic capacitor 10 according to the present embodiment, the stacking direction of the internal electrodes 12 and 13 is the in-plane direction of the base material 211, and thus vibration in the thickness direction is less likely to be generated in the base material 211 due to the electrostriction of the ceramic body 11. In the multilayer ceramic capacitor 10, the number of stacked internal electrodes 12 and 13 is small, and the amount of deformation due to electrostriction is kept small. Therefore, even when vibration is generated in the base material 211, the vibration is unlikely to be so large as to generate noise sound.

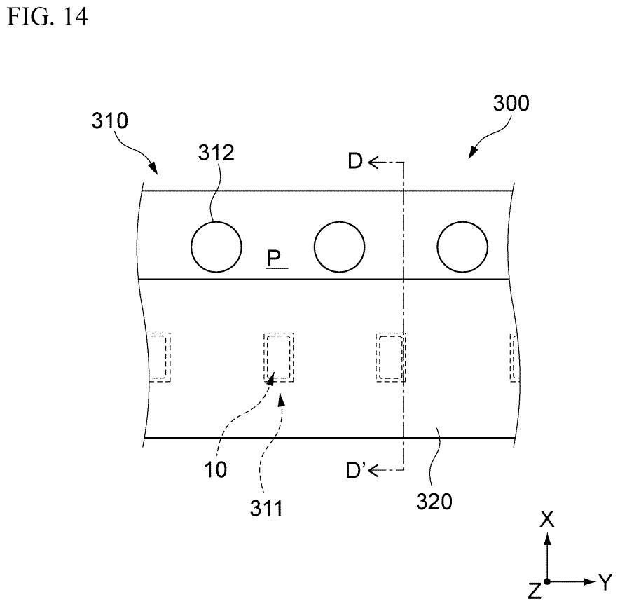

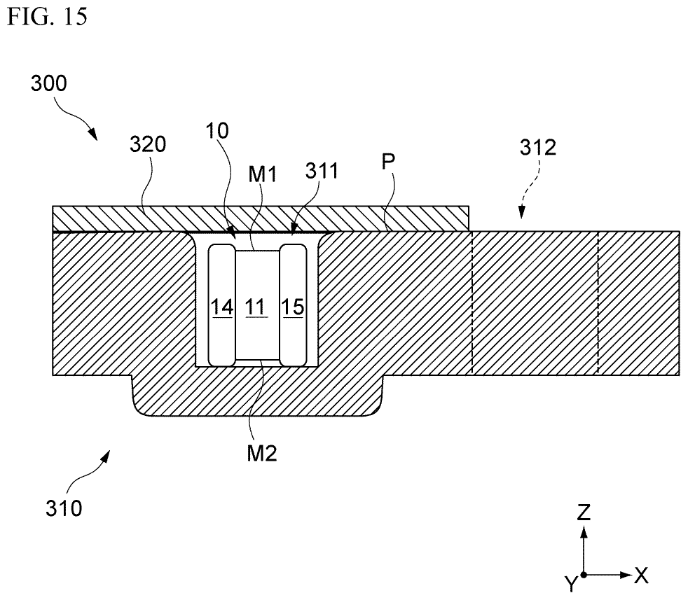

The multilayer ceramic capacitor 10 is prepared in a state of being packaged as a package 300 when being mounted on the mounting substrate 210. FIG. 14 and FIG. 15 illustrate the package 300. FIG. 14 is a partial plan view of the package 300. FIG. 15 is a cross-sectional view of the package 300 taken along line D-D′ in FIG. 14.

The package 300 includes the multilayer ceramic capacitor 10, a carrier tape 310, and a top tape 320. The carrier tape 310 is configured as a long tape extending in the Y-axis direction. In the carrier tape 310, a plurality of recesses 311 each accommodating one multilayer ceramic capacitor 10 are arranged at intervals in the Y-axis direction.

The carrier tape 310 has a sealing surface P that is an upward-facing surface orthogonal to the Z-axis, and the plurality of recesses 311 are recessed downward in the Z axis direction from the sealing surface P. That is, the carrier tape 310 is configured so that the multilayer ceramic capacitors 10 in the plurality of recesses 311 can be taken out from the sealing surface P side.

In the carrier tape 310, a plurality of feed holes 312 penetrating through the carrier tape 310 in the Z-axis direction and being arranged at intervals in the Y-axis direction are provided at positions shifted in the X-axis direction from the row of the plurality of recesses 311. The feed holes 312 are configured as engagement holes used for the tape transport mechanism to transport the carrier tape 310 in the Y-axis direction.

In the package 300, the top tape 320 is attached to the sealing surface P of the carrier tape 310 along the row of the plurality of recesses 311, and the plurality of recesses 311 accommodating the plurality of multilayer ceramic capacitors 10 are collectively covered with the top tape 320. Thus, the plurality of multilayer ceramic capacitors 10 are held in the plurality of recesses 311.

As illustrated in FIG. 14, in the multilayer ceramic capacitor 10 in the recess 311 of the carrier tape 310, the first main surface M1 of the ceramic body 11 facing upward in the Z-axis direction faces the top tape 320. The second main surface M2 of the ceramic body 11 facing downward in the Z-axis direction faces the bottom surface of the recess 311.

When the multilayer ceramic capacitor 10 packaged as the package 300 is mounted, the top tape 320 is peeled off from the sealing surface P of the carrier tape 310 along the Y-axis direction. This allows the plurality of recesses 311 in which the plurality of multilayer ceramic capacitors 10 are accommodated to be sequentially opened upward in the Z-axis direction in the package 300.

The multilayer ceramic capacitor 10 accommodated in the opened recess 311 is taken out in a state where the first main surface M1 of the ceramic body 11 facing upward in the Z-axis direction is sucked by the tip of a suction nozzle of a mounting device. In the multilayer ceramic capacitor 10, the flatness of the first main surface M1 of the ceramic body 11 is high, and thus the multilayer ceramic capacitor 10 can be more reliably sucked by a suction nozzle.

Subsequently, the mounting device moves the suction nozzle to cause the second main surface M2 of the ceramic body 11 to face the mounting surface G, and releases the suction of the first main surface M1 of the ceramic body 11 by the suction nozzle in a state where the external electrodes 14 and 15 are aligned on the pair of connection electrodes 212 to which the solder paste is applied. Thus, the multilayer ceramic capacitor 10 is mounted on the mounting surface G.

Then, the solder paste is melted and then hardened by using a reflow furnace or the like with respect to the mounting substrate 210 with the mounting surface G on which the multilayer ceramic capacitor 10 is placed. This causes the external electrodes 14 and 15 of the multilayer ceramic capacitor 10 to be connected to the pair of connection electrodes 212 of the mounting substrate 210 through the solder H, and thereby the circuit board 200 illustrated in FIG. 13 is obtained.

In the multilayer ceramic capacitor 10, in the process from when the multilayer ceramic capacitor 10 is placed on the mounting surface G to when the solder H is hardened, a stable posture in which the second main surface M2 having a high flatness opposes the mounting surface G in parallel is likely to be maintained. Thus, in the circuit board 200, a short circuit caused by the multilayer ceramic capacitor 10 tilting and contacting an adjacent component is less likely to occur.

### Second Embodiment

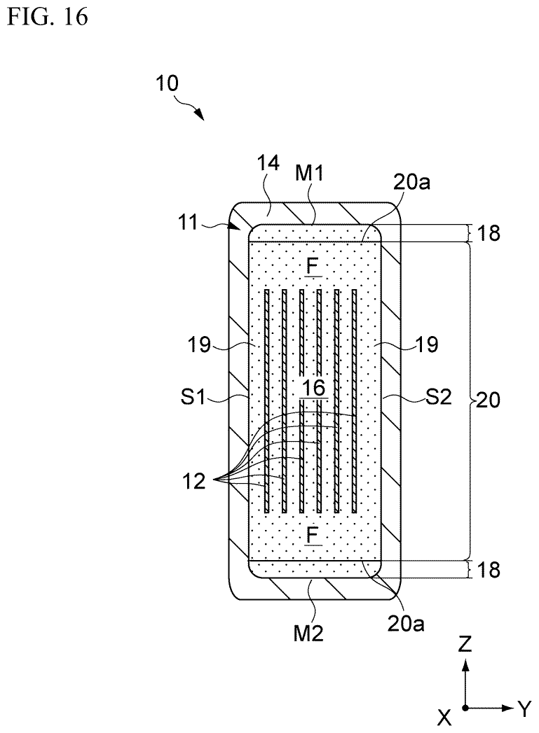

The multilayer ceramic capacitor 10 according to a second embodiment of the present disclosure is different from the multilayer ceramic capacitor 10 according to the first embodiment only in the configuration of the internal electrodes 12 and 13, and has the appearance illustrated in FIG. 1, similarly to the multilayer ceramic capacitor 10 according to the first embodiment. FIG. 16 to FIG. 18 illustrate the multilayer ceramic capacitor 10 according to the second embodiment.

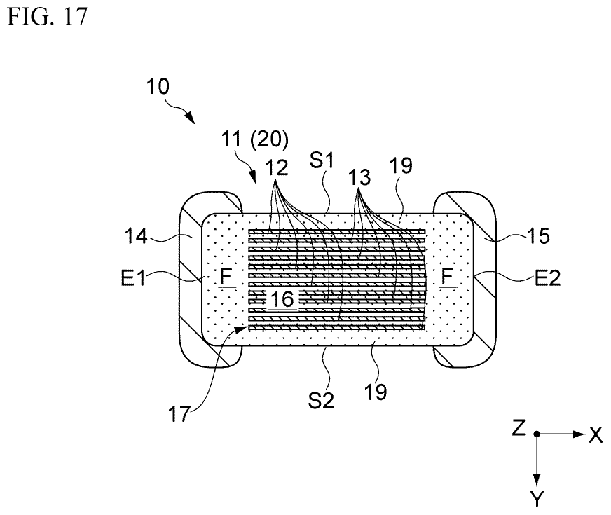

FIG. 16 is a vertical cross-sectional view of the multilayer ceramic capacitor 10 taken along line A2-A2′ in FIG. 1. FIG. 17 is a horizontal cross-sectional view of the multilayer ceramic capacitor 10 taken along line B2-B2′ in FIG. 1. FIG. 16 and FIG. 17 illustrate cross-sections of a section including the vicinities of ridge portions extending in the Y-axis direction of the ceramic body 11 in the multilayer ceramic capacitor 10.

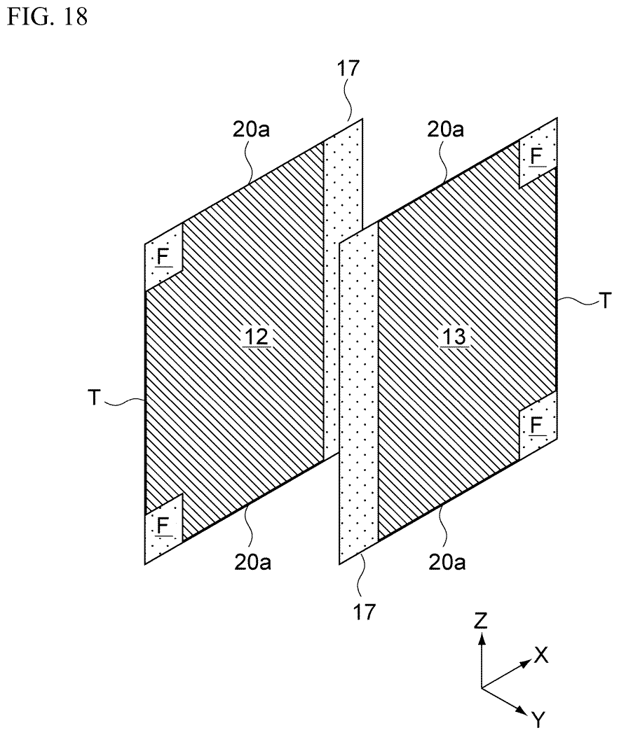

FIG. 18 illustrates one dielectric layer 17 on which the first internal electrode 12 is formed and one dielectric layer 17 on which the second internal electrode 13 is formed, among the dielectric layers 17 constituting the electrode stacking portion 16. In the electrode stacking portion 16 according to the present embodiment, the planar shapes of the internal electrodes 12 and 13 are different from those in the electrode stacking portion 16 according to the first embodiment.

The internal electrodes 12 and 13 have absent regions F, where no electrode material is arranged, in sections, which extend in the Y-axis direction and includes the vicinities of four ridge portions, of the ceramic body 11 in the electrode stacking portion 16. That is, the internal electrodes 12 and 13 are disposed so as to avoid the sections extending in the Y-axis direction near the four ridge portions of the ceramic body 11.

As illustrated in FIG. 18, each of the internal electrodes 12 and 13 has the absent regions F each formed in a rectangular cutout shape on both sides in the Z-axis direction in the end portion in the X-axis direction including the connection end T. Thus, each of the internal electrodes 12 and 13 has a planar shape that is narrowed inward from both sides in the Z-axis direction in the end portion in the X-axis direction including the connection end T.

In the inner electrodes 12 and 13, the respective distances from the main surfaces M1 and M2 are larger in the end portion in the X-axis direction including the connection end T than in the central portion in the X-axis direction because the absence regions F are provided. In the ceramic body 11, when the absence regions F are provided in all the internal electrodes 12 and 13, the internal electrodes 12 and 13 are absent near the four ridge portions along the Y-axis direction.

When the external electrodes 14 and 15 are fired onto the ceramic body 11 in step S06 of the above-described manufacturing method, components in the external electrodes 14 and 15 may diffuse into the internal electrodes 12 and 13 from the connection ends T, respectively. Thus, the end portions including the connection ends T in the X-axis direction in the internal electrodes 12 and 13 expand in the thickness direction along the Y-axis.

This phenomenon is remarkably observed in a configuration in which the main component of the internal electrodes 12 and 13 is Ni and the main component of the external electrodes 14 and 15 is Cu, for example. That is, in this case, in the internal electrodes 12 and 13, Ni constituting the end portion in the X-axis direction including the connection end T reacts with Cu to form a copper-nickel alloy, and thus expansion in the thickness direction occurs.

In the ceramic body 11, internal stress caused by expansion in the Y-direction of only both end portions in the X-axis direction is likely to concentrate on the corner portions. Here, the corner portions of the ceramic body 11 refer to eight portions that connect three surfaces of the main surfaces M1 and M2, the end surfaces E1 and E2, and the side surfaces S1 and S2 to each other.

In the ceramic body 11, as the internal stress concentrated on the corner portion is increased, a crack is more likely to be generated in the corner portion. In the multilayer ceramic capacitor 10, when a crack is generated in a corner portion of the ceramic body 11, the crack serves as a path through which moisture enters, and thus the moisture resistance is likely to be reduced. In addition, in the ceramic body 11, since the corner portions are covered with the external electrodes 14 and 15, it is difficult to find cracks generated in the corner portions by visual inspection.

In this regard, in the multilayer ceramic capacitor 10 according to the present embodiment, as described above, no internal electrodes 12 and 13 are present near the four ridge portions along the Y-axis direction by providing the absence regions F in the internal electrodes 12 and 13. That is, in the internal electrodes 12 and 13, the distances from the main surfaces M1 and M2 are larger in the connection ends T than in the central portion in the X-axis direction.

Thus, in the ceramic body 11, the corner portions are less likely to be affected by the expansion of the internal electrodes 12 and 13. In the ceramic body 11, internal stress caused by expansion of the internal electrodes 12 and 13 is reduced in the vicinities of the four ridge portions. Therefore, in the ceramic body 11, the generation of cracks in the corner portions can be effectively reduced.

In the internal electrodes 12 and 13, as the dimension of the absence region F in the Z-axis direction increases, the respective distances from the main surfaces M1 and M2 of the ceramic body 11 increase. Therefore, the generation of cracks in the ceramic body 11 can be more effectively inhibited. Thus, from this viewpoint, the dimension of the absence region in the Z-axis direction is preferably large.

On the other hand, in the internal electrodes 12 and 13, as the dimension of the absence region F in the Z-axis direction decreases, the respective connection areas to the external electrodes 14 and 15 at the connection ends T increase. Therefore, the occurrence of the poor connection to the external electrodes 14 and 15 can be more effectively inhibited. Therefore, from this viewpoint, it is not preferable that the dimension of the absence region F in the Z-axis direction is too large.

Therefore, specifically, in the internal electrodes 12 and 13, the dimension of the connection end T in the Z-axis direction is preferably equal to or less than 90% of, more preferably equal to or less than 80% of the dimension in the Z-axis direction of the central portion in the X-axis direction. In the internal electrodes 12 and 13, the dimension of the connection end T in the Z-axis direction is preferably equal to or greater than 60% of, more preferably equal to or greater than 70% of the dimension in the Z-axis direction of the central portion in the X-axis direction.

As illustrated in FIG. 17, the absence regions F of the internal electrodes 12 and 13 preferably extend to the positions inwardly beyond the portions of the external electrodes 14 and 15 extending to the main surfaces M1 and M2 in the X-axis direction. This can inhibit the generation of cracks in the portions of the ceramic body 11 covered with the external electrodes 14 and 15, which are difficult to visually inspect.

In the multilayer ceramic capacitor 10, all the internal electrodes 12 and 13 preferably have the absence regions F, but some of the internal electrodes 12 and 13 may not necessarily have the absence regions F. In this case, the absence region F is preferably provided in the internal electrodes 12 and 13 located in at least sections adjacent to the pair of cover portions 19.

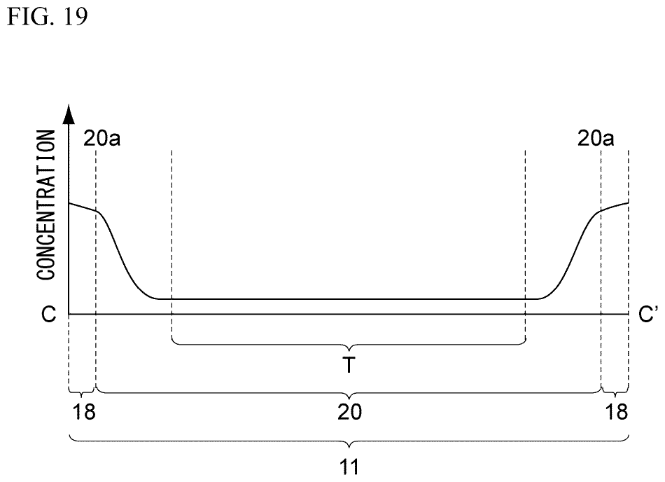

FIG. 19 is a graph presenting the concentration distribution of the grain growth inhibiting element along the line C-C′ in FIG. 2 in the ceramic body 11. That is, FIG. 19 illustrates the concentration distribution of the grain growth inhibiting element along the Z-axis direction in the central portion of the ceramic body 11 in the X-axis and Y-axis directions. In FIG. 19, the horizontal axis represents the position, and the vertical axis represents the concentration of the grain growth inhibiting element.

As illustrated in FIG. 19, the multilayer body 20 preferably has a substantially constant concentration of the grain growth inhibiting element in the section where the connection end T is present in the Z-axis direction, and is preferably not affected by diffusion of the grain growth inhibiting element from the pair of margin portions 18. Thus, in the multilayer ceramic capacitor 10, a decrease in capacitance can be more effectively inhibited.

### Example

As Example 1 of the present disclosure, a sample of the multilayer ceramic capacitor 10 according to the first embodiment described above was fabricated. In addition, as Example 2 of the present disclosure, a sample of the multilayer ceramic capacitor 10 according to the second embodiment described above was fabricated. One hundred samples were prepared for each of Examples 1 and 2.

As Example 3 of the present disclosure, a sample of the multilayer ceramic capacitor 10 according to the first embodiment described above was fabricated. In addition, as Example 4 of the present disclosure, a sample of the multilayer ceramic capacitor 10 according to the second embodiment described above was fabricated. One hundred samples were prepared for each of Examples 3 and 4.

In all the samples according to Examples 1 and 2, the dimension in the length direction along the X-axis was 600 μm, the dimension in the width direction along the Y-axis was 300 μm, and the dimension in the height direction along the Z-axis was 500 μm. In all the samples of Examples 1 and 2, the thickness of each of the pair of margin portions 18 was 20 km.

In all the samples of Examples 3 and 4, the dimension in the length direction along the X-axis was 600 μm, the dimension in the width direction along the Y-axis was 300 μm, and the dimension in the height direction along the Z-axis was 400 km. In all the samples of Examples 3 and 4, the thickness of each of the pair of margin portions 18 was 20 km.

In the samples of Example 1, the dimension of the internal electrodes 12 and 13 in the Z-axis direction was 460 km. In the samples of Example 2, the dimension in the Z-axis direction of the central portion in the X-axis direction of each of the internal electrodes 12 and 13 was 460 km. In the samples of Example 2, the dimension in the Z-axis direction of the portion narrowed in the Z-axis direction in the end portion in the X-axis direction including the connection end T of each of the internal electrodes 12 and 13 was 400 μm, and the dimension in the X-axis direction was 30 km.

In the samples of Example 3, the dimension of each of the internal electrodes 12 and 13 in the Z-axis direction was 360 μm. In the samples of Example 4, the dimension in the Z-axis direction of the central portion in the X-axis direction of each of the internal electrodes 12 and 13 was 360 μm. In the samples of Example 4, the dimension in the Z-axis direction of the portion narrowed in the Z-axis direction in the end portion in the X-axis direction including the connection end T of each of the internal electrodes 12 and 13 was 300 μm, and the dimension in the X-axis direction was 30 km.

In all the samples of Examples 1 and 2, the thickness of each of the internal electrodes 12 and 13 and the thickness of each dielectric layer 17 were all 0.5 μm. In the samples of Examples 1 and 2, the total number of stacked internal electrodes 12 and 13 was 260.

In the samples of Examples 3 and 4, the thickness of each of the internal electrodes 12 and 13 and the thickness of each dielectric layer 17 were all 0.5 μm. In each of the samples of Examples 3 and 4, the total number of stacked internal electrodes 12 and 13 was 260.

In the samples of Examples 1 and 2, the grain growth inhibiting element was added to the pair of margin portions 18 at a higher concentration than in the multilayer body 20 before firing. In addition, in the samples of Examples 1 and 2, one of the following elements: Mg, Mn, and rare earth elements (Y, Dy, Ho, Er, and Yb) was used as the grain growth inhibiting element.

In all the samples of Examples 3 and 4, the grain growth inhibiting element was added to the pair of margin portions 18 at a higher concentration than the multilayer body 20 before firing. In addition, in all the samples of Examples 3 and 4, one of the following elements: Mg, Mn, and rare earth elements (Y, Dy, Ho, Er, and Yb) was used as the grain growth inhibiting element.

In addition, as Comparative Example of the present disclosure, 100 samples having a general configuration in which the stacking direction of the first and second internal electrodes was the height direction were fabricated. In the samples of Comparative Example, the dimension in the length direction, the dimension in the width direction, the dimension in the height direction, the thickness of the margin portion, the thickness of each of the first and second internal electrodes, and the thickness of each of the dielectric layers were set to be equivalent to those of the samples of Examples 1 and 2.

In the samples of Comparative Example, the first and second internal electrodes were not formed in a shape narrowed in the end portion including the connection end, that is, the first and second internal electrodes had no absence region. In the samples of Comparative Example, the dimension in the width direction of each of the first and second internal electrodes was 260 μm, and the total number of stacked first and second internal electrodes was 460.

In the samples of Comparative Example, the grain growth inhibiting element was added to a pair of margin portions covering the multilayer body from respective sides in the width direction before firing so that the concentration of the grain growth inhibiting element was higher than that of the multilayer body 20. In the samples of Comparative Example, the same metal as in Examples 1 and 2 was used as the grain growth inhibiting element.

The electrostatic capacitance was measured under the conditions of 1 kHz and 0.5 Vrms for 100 samples of each of Examples 1 and 2 and Comparative Example. For each of the configurations of Examples 1 and 2 and Comparative Example, the design value of the electrostatic capacitance was obtained using the design value of the relative permittivity of the dielectric layer, and the decrease ratio of the electrostatic capacitance was obtained as the ratio of the amount of decrease in electrostatic capacitance from the design value to the design value.

The electrostatic capacitance was measured for 100 samples of each of Examples 3 and 4 under the conditions of 1 kHz and 0.5 Vrms. For each of the configurations of Examples 3 and 4, the design value of the electrostatic capacitance was obtained using the design value of the relative permittivity of the dielectric layer, and the decrease ratio of the electrostatic capacitance was obtained as the ratio of the amount of decrease in electrostatic capacitance from the design value to the design value.

In all the samples of Examples 1 and 2, the decrease ratio of the electrostatic capacitance was within a range of 5%. In contrast, in the samples of Comparative Example, the average value of the decrease ratio of the electrostatic capacitance was 10% or more. Thus, it was confirmed that in the samples of Examples 1 and 2, a decrease in electrostatic capacitance is inhibited more than in the samples of Comparative Example.

This is considered to be because, in the samples of Examples 1 and 2, the ratio of the section where the dielectric layer is affected by the diffusion of the grain growth inhibiting element to the entire section where the first and second internal electrodes face each other was kept smaller than in the samples of Comparative Example. That is, it is understood that the configurations of Examples 1 and 2 are more advantageous than the configuration of Comparative Example in order to secure a large capacity.

In all the samples of Examples 3 and 4, the decrease ratio of the electrostatic capacitance was within a range of 5%. Thus, it was confirmed that in the samples of Examples 3 and 4, a decrease in electrostatic capacitance was smaller than in the samples of Comparative Example.

This is considered to be because, in the samples of Examples 3 and 4, the ratio of the section where the dielectric layer is affected by the diffusion of the grain growth inhibiting element to the entire section where the first and second internal electrodes face each other was smaller than in the samples of Comparative Example. That is, it is found that the configurations of Examples 3 and 4 are more advantageous than the configuration of Comparative Example in order to secure a large capacity.

Next, a reliability test was performed on 100 samples of each of Examples 1 and 2 and Comparative Example by applying a direct current voltage of 10 V under an environment of 105° C. In each of Examples 1 and 2 and Comparative Example, no samples reached dielectric breakdown in less than 500 hours, and it is considered that the effect of inhibiting the grain growth of the dielectric layer by the grain growth inhibiting element was sufficiently obtained.

A reliability test was performed on 100 samples of each of Examples 3 and 4 by applying a direct current voltage of 10 V in an environment of 105° C. In both Examples 3 and 4, no samples reached dielectric breakdown in less than 500 hours, and it is considered that the effect of inhibiting the grain growth of the dielectric layer by the grain growth inhibiting element was sufficiently obtained.

### Other Embodiments

Although the embodiment of the present invention has been described in detail above, the present invention is not limited to the specific embodiment, and various modifications and changes can be made within the scope of the gist of the present invention described in the claims.

For example, in the multilayer ceramic capacitor 10, the first main surface M1 and the second main surface M2 of the ceramic body 11 may be reversed. That is, in the circuit board 200 illustrated in FIG. 13 and the multilayer ceramic capacitor 10 in the package 300 illustrated in FIG. 15, the first main surface M1 may face downward in the Z-axis direction and the second main surface M2 may face upward in the Z-axis direction.

The shape of the absence region F in each of the internal electrodes 12 and 13 according to the second embodiment may be changed within a range in which the effect of the present invention is exhibited. For example, the absence region F of each of the internal electrodes 12 and 13 may have an outline form including a curve. In the internal electrodes 12 and 13, the shapes of the absence regions F may be different between the first main surface M1 side and the second main surface M2 side.

What is claimed is:

1. A multilayer ceramic capacitor that has a dimension in a first direction along a first axis equal to or greater than 1.5 times a dimension in a second direction along a second axis orthogonal to the first axis, and is configured to be mounted on a mounting surface perpendicular to the first axis, the multilayer ceramic capacitor comprising:
a ceramic body having:
a pair of main surfaces perpendicular to the first axis,
a pair of side surfaces perpendicular to the second axis,
an end surface perpendicular to a third axis orthogonal to the first axis and the second axis,
a multilayer body including a plurality of internal electrodes that are stacked in the second direction and are led out to a connection end on the end surface, and
a pair of margin portions that cover the multilayer body from respective sides in the first direction, and have a higher concentration of a grain growth inhibiting element than the multilayer body; and
an external electrode covering the end surface.

2. The multilayer ceramic capacitor according to claim 1, wherein the grain growth inhibiting element is at least one of the following elements: Mg, Mn, and a rare earth element.

3. The multilayer ceramic capacitor according to claim 1, wherein the pair of main surfaces have higher flatness than the pair of side surfaces in the ceramic body.

4. The multilayer ceramic capacitor according to claim 1, wherein the plurality of internal electrodes have larger distances from the pair of main surfaces at the connection end than in a central portion in a third direction along the third axis.

5. The multilayer ceramic capacitor according to claim 4, wherein, in the plurality of internal electrodes, a dimension of the connection end in the first direction is equal to or greater than 60% of and equal to or less than 90% of a dimension in the first direction of the central portion in the third direction.

6. The multilayer ceramic capacitor according to claim 4, wherein in the multilayer body, the concentration of the grain growth inhibiting element is substantially constant in a section where the connection end is present in the first direction.

7. A package comprising:
the multilayer ceramic capacitor according to claim 1;
a carrier tape having a sealing surface perpendicular to the first axis and a recess that is recessed from the sealing surface in the first direction and accommodates the multilayer ceramic capacitor; and
a top tape that is attached to the sealing surface and covers the recess.

8. A circuit board comprising:
the multilayer ceramic capacitor according to claim 1; and
a mounting substrate having a mounting surface perpendicular to the first axis, and a connection electrode that is provided on the mounting surface and connected to the external electrode of the multilayer ceramic capacitor through solder.

9. A multilayer ceramic capacitor that has a dimension in a first direction along a first axis equal to or greater than 1.3 times a dimension in a second direction along a second axis orthogonal to the first axis, and is configured to be mounted on a mounting surface perpendicular to the first axis, the multilayer ceramic capacitor comprising:
a ceramic body having:
a pair of main surfaces perpendicular to the first axis,
a pair of side surfaces perpendicular to the second axis,
an end surface perpendicular to a third axis orthogonal to the first axis and the second axis,
a multilayer body including a plurality of internal electrodes that are stacked in the second direction and are led out to a connection end on the end surface, and
a pair of margin portions that cover the multilayer body from respective sides in the first direction and have a higher concentration of a grain growth inhibiting element than the multilayer body; and
an external electrode covering the end surface.

10. The multilayer ceramic capacitor according to claim 9, wherein the grain growth inhibiting element is at least one of the following elements: Mg, Mn, and a rare earth element.

11. The multilayer ceramic capacitor according to claim 9, wherein the pair of main surfaces have higher flatness than the pair of side surfaces in the ceramic body.

12. The multilayer ceramic capacitor according to claim 9, wherein the plurality of internal electrodes have larger distances from the pair of main surfaces at the connection end than in a central portion in a third direction along the third axis.

13. The multilayer ceramic capacitor according to claim 12, wherein, in the plurality of internal electrodes, a dimension of the connection end in the first direction is equal to or greater than 60% of and equal to or less than 90% of a dimension in the first direction of the central portion in the third direction.

14. The multilayer ceramic capacitor according to claim 12, wherein in the multilayer body, the concentration of the grain growth inhibiting element is substantially constant in a section where the connection end is present in the first direction.

15. A package comprising:
the multilayer ceramic capacitor according to claim 9;
a carrier tape having a sealing surface perpendicular to the first axis and a recess that is recessed from the sealing surface in the first direction and accommodates the multilayer ceramic capacitor; and
a top tape that is attached to the sealing surface and covers the recess.

16. A circuit board comprising:
the multilayer ceramic capacitor according to claim 9; and
a mounting substrate having a mounting surface perpendicular to the first axis, and a connection electrode that is provided on the mounting surface and connected to the external electrode of the multilayer ceramic capacitor through solder.
